(19) United States
(12) Patent Application Publication
(10) Pub. No.: US 2007/0215997 A1
(43) Pub. Date: Sep. 20, 2007

(54) Chip-scale package

(76) Inventor: Martin Standing, Tonbridge (GB)

Correspondence Address: OSTROLENK FABER GERB & SOFFEN, 1180 AVENUE OF THE AMERICAS, NEW YORK, NY, 100368403, US

(21) Appl. No.: 11/378,607

(22) Filed: Mar. 17, 2006

(51) Int. Cl. H01L 23/02

(52) U.S. Cl. 257/678

(57) ABSTRACT

A power semiconductor package that includes a die having one electrode thereof electrically and mechanically attached to a web portion of a conductive clip.

### BACKGROUND OF THE INVENTION

The present invention relates to power semiconductor packages.

Referring to FIGS. 1-7, a package 10 according to the prior art includes a conductive can 12, and a power semiconductor die 14. Can 12 is typically formed with an electrically conductive material such as copper or a copper-based alloy, and may be coated with silver, gold or the like. Die 14 may be a vertical conduction type power semiconductor MOSFET having its drain electrode 16 electrically and mechanically attached to an interior surface of can 12 by a conductive adhesive 18 such as solder or a conductive epoxy (e.g. silver epoxy). Source electrode 20, and gate electrode 22 of die 14 (which are disposed on a surface opposite to the drain electrode) each includes a solderable body which facilitates its direct connection to a respective conductive pad 24, 26 of a circuit board 28 by conductive adhesive (e.g. solder or conductive epoxy) as illustrated by FIG. 8. Note that die 14 further includes passivation body 30 which partially covers source electrode 20 and gate electrode 22, but includes openings to allow access at least to the solderable portions thereof for electrical connection. Note that in package 10 conductive can 12 includes web portion 13 (to which die 14 is electrically and mechanically connected), wall 15 surrounding web portion 13, and two oppositely disposed rails 32 extending from wall 15 each configured for connection to a respective conductive pad 34 on circuit board 28. Also, note that die 14 is spaced from wall 13 of can 12; i.e. wall 13 surrounds die 14. Thus, a moat 36 is present between die 14 and wall 13. Further because flange portions 17 of wall 15 are exposed, the creepage distance between the active electrodes of die 14 and can 12 is roughly the width of moat 36.

In a package according to the prior art, source electrode 20, and gate electrode 22 are soldered down by the user. Specifically, the user applies solder to, for example, the pads of a circuit board, and the electrodes of the die are attached to the pads by the solder so placed.

A package as described above is shown in U.S. Pat. No. 6,624,522. In one prior art variation (see U.S. Pat. No. 6,930,397) die 14 is recessed interiorly of can 12 such that it is spaced from the contact surfaces of rails 32. A benefit of recessing die 14 is to allow for clearance 33 (FIG. 8) between passivation body 30 on die 14 and circuit board 28 for cleaning (e.g. flux flushing) after solder reflow. In one prior art package, clearance 33 between passivation body 30 and circuit board 28 is about 30 μm.

It is desirable to increase clearance 33 to enable an increased volume of air to flow under the package during lead free reflow conditions and allow volatiles present within the solder paste to escape.

Increasing clearance 33 between the die and circuit board also allows the joints to be visually inspected.

### SUMMARY OF THE INVENTION

A package according to one embodiment of the present invention includes a die having solder bodies pre-printed thereon. The pre-printed solder bodies allow for a stand off between the passivation body on the die and the support body (e.g. circuit board). The stand off allows for a clearance between the passivation body on the die and the support body which aids in de-gassing, and the release of volatile flux components. US 2005/0121784, which is assigned to the assignee of the present invention, discloses a package having a die with interconnects formed with a paste containing conductive particles that are glued to one another with a solder matrix. The interconnects can provide the desired clearance, but are expensive. The advantage of using only solder paste, in a package according to the present invention, is that the needed clearance can be attained with lower cost.

According to another embodiment each of the rails of the can includes a plurality of bumps. The bumps also provide for a stand off with advantages similar to the stand off provided by the pre-printed solder bodies. Note that in the case of pre-printed solder bodies as well as bumps on the rails the die is not required to be recessed interiorly of the can to provide the desired clearance (although it may be recessed optionally to obtain further clearance). Thus, neither the depth of the can nor the thickness of the die need to be changed if more standoff is desired. That is, the desired stand off is independent of the can depth and the thickness of the die in an arrangement according to the first and the second embodiments.

In another embodiment of the present invention, the single layer passivation is replaced with a double layer passivation that includes a first passivation layer of a first passivation material and a second passivation layer of a second passivation material. It has been found that such an arrangement forms an improved barrier to the by-products of lead free fluxes.

According to another aspect of the present invention, the passivation fills the moat around the die and is extended to fully cover the flange portion of the walls of the can in order to increase the creepage distance.

Other features and advantages of the present invention will become apparent from the following description of the invention which refers to the accompanying drawings.

### BRIEF DESCRIPTION OF THE FIGURES

FIG. 1 is a perspective view of a package according to prior art.

FIG. 2 is another perspective view of the package of FIG. 1.

FIG. 3 is a top plan view of the package of FIG. 1.

FIG. 4 is a bottom plan view of the package of FIG. 1.

FIG. 5 is a side elevational view of the package of FIG. 1.

FIG. 6 is a side elevational view of the package of FIG. 1.

FIG. 7 is a cross-sectional view of the package of FIG. 1 along line 7-7 in FIG. 4.

FIG. 8 shows the package of FIG. 1 as assembled on a circuit board.

FIG. 9 illustrates a cross-sectional view of a package according to one embodiment of the present invention.

FIG. 10 illustrates a cross-sectional view of a package according to another embodiment of the present invention.

FIG. 11A illustrates a bottom plan view of a can of a package in an embodiment of the present invention.

FIG. 11B shows a cross-sectional view of the can shown in FIG. 11A along line B-B viewed in the direction of the arrows.

FIG. 11C shows a cross-sectional view of the can shown in FIG. 11A along line A-A viewed in the direction of the arrows.

FIG. 11D shows a cross-sectional view of the can shown in FIG. 11A along line C-C viewed in the direction of the arrows.

FIG. 11E illustrates a cross-sectional view of a package according to another embodiment of the present invention which includes a can according to FIGS. 11A-11D.

FIG. 12 illustrates a package according to another embodiment of the present invention.

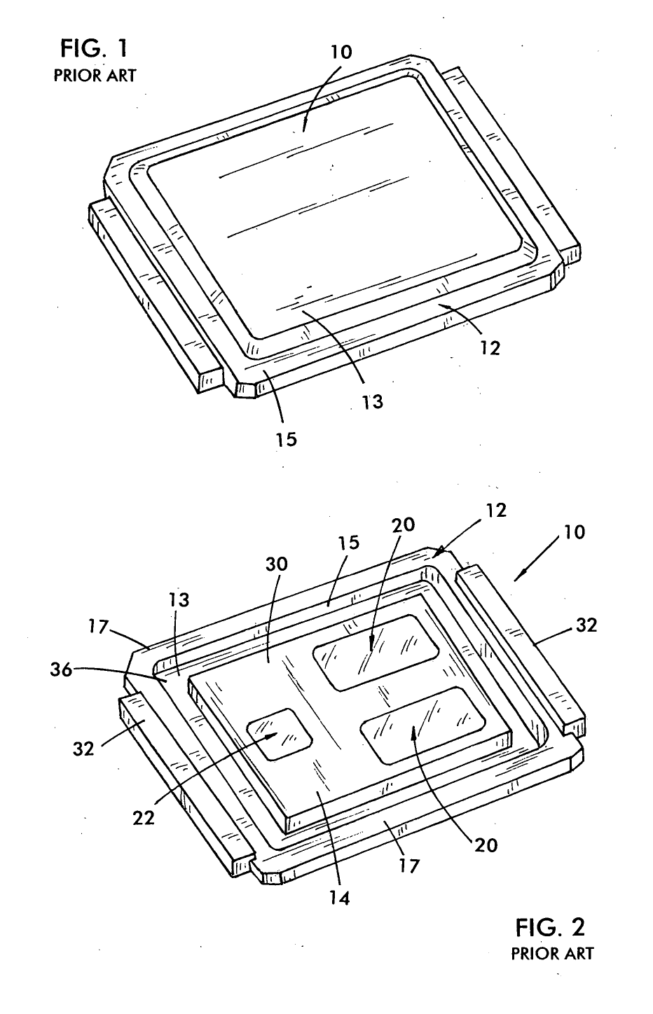

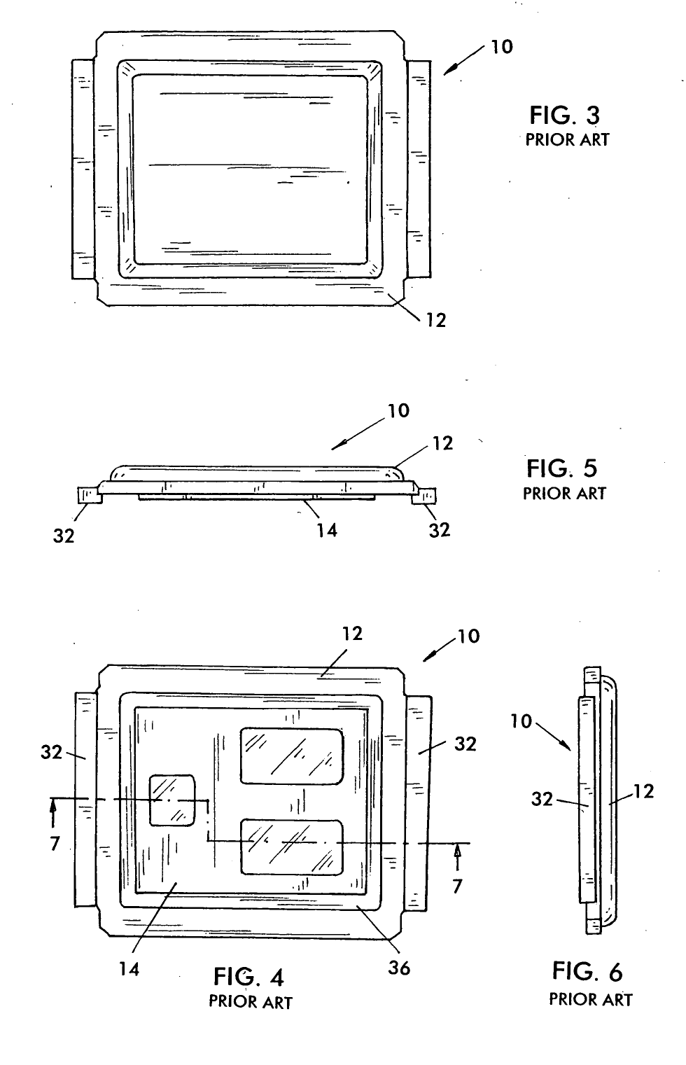

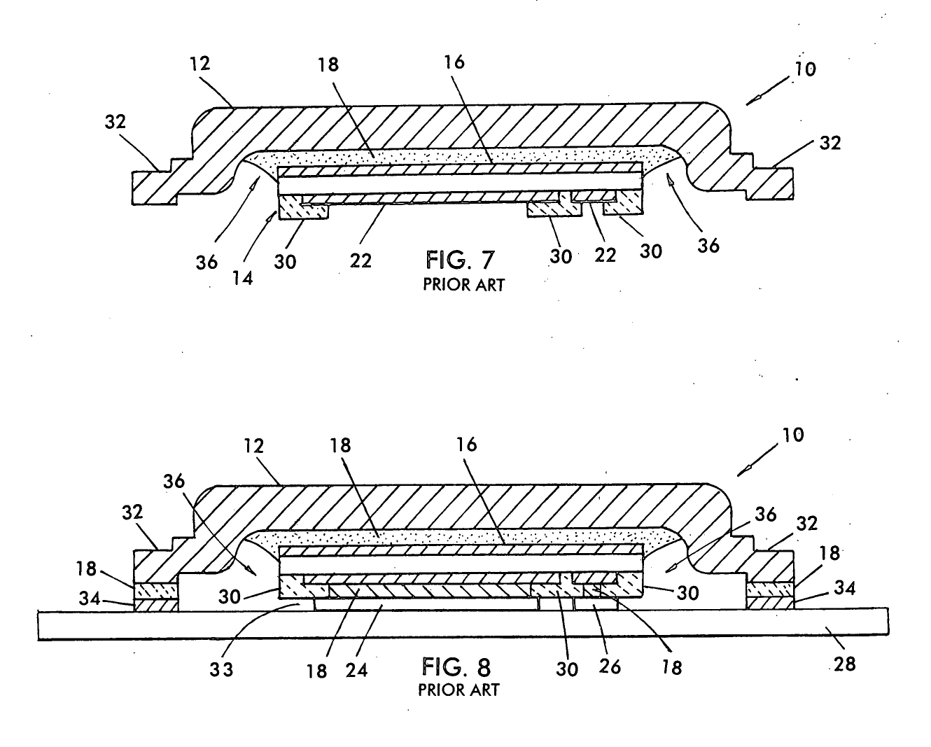

### DETAILED DESCRIPTION OF EMBODIMENTS OF THE INVENTION

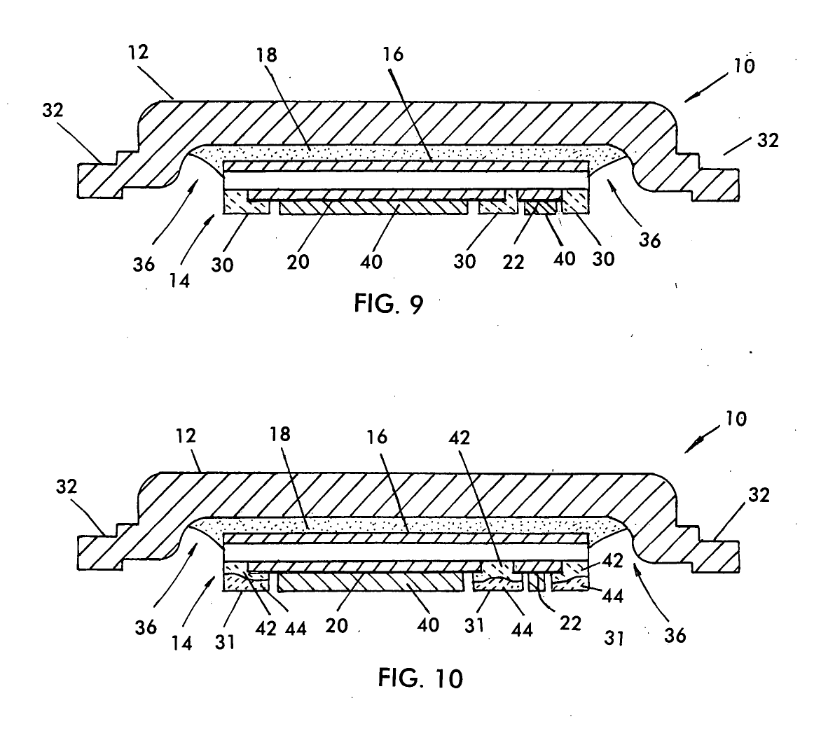

Referring to FIG. 9 in which like numerals identify like features, in an improved package according to the present invention, source electrode 20 and gate electrode 22 are pre-soldered with a solder body 40. Pre-soldering of the package ensures proper, and well controlled stand-off between passivation body 30 of die 14 and the pads of a circuit board when the package is installed. Presoldering electrodes 20, 22 on die 14 surface also improves solder wetting during the reflow process and increases the reflow process window. A preferred solder for forming solder bodies 40 is a lead-free solder such as SnAgCu, or SnSb. Solder bodies 40 may extend beyond passivation body 30, and may be any desired thickness e.g. 120 μm, or 175 μm.

To fabricate a die 14 having solder bodies 40, die 14 is processed while in a wafer to have solder bodies 40 printed thereon. Specifically, each die 14, in a wafer having a plurality of die 14, has solder bodies 40 printed thereon using a stencil with pre-etched apertures. Solder is printed through the apertures onto designated areas of electrodes 20,22. The wafer containing areas of localised solder paste is then re-flowed in a reflow oven. After reflow, the wafer containing an array of die 14 with pre-soldered electrodes is cleaned to remove any residual flux. The cleaning agent may be aqueous or solvent based.

Referring to FIG. 10, in an improved package according to another embodiment of the present invention, passivation body 31 includes first passivation body 42, and second passivation body 44 over first passivation body 42. In the preferred embodiment, first passivation body 42 may be a silicon epoxy, e.g. EP3912, and second passivation body 44 may be formed with a carbon-based epoxy, e.g. EP2793. This combination has been found to be particularly suitable when lead-free solder is used to connect source electrode 20 or gate electrode 22 to a conductive pad on a circuit board. Note that second passivation 44 can be used as a hardmask to open contact openings in first passivation 42, and serves as an additional protection layer. In the preferred embodiment, die 14 in the package illustrated by FIG. 10 also includes solder bodies 40. It should be appreciated, however, a package without solder bodies 40 is within the scope of the present invention.

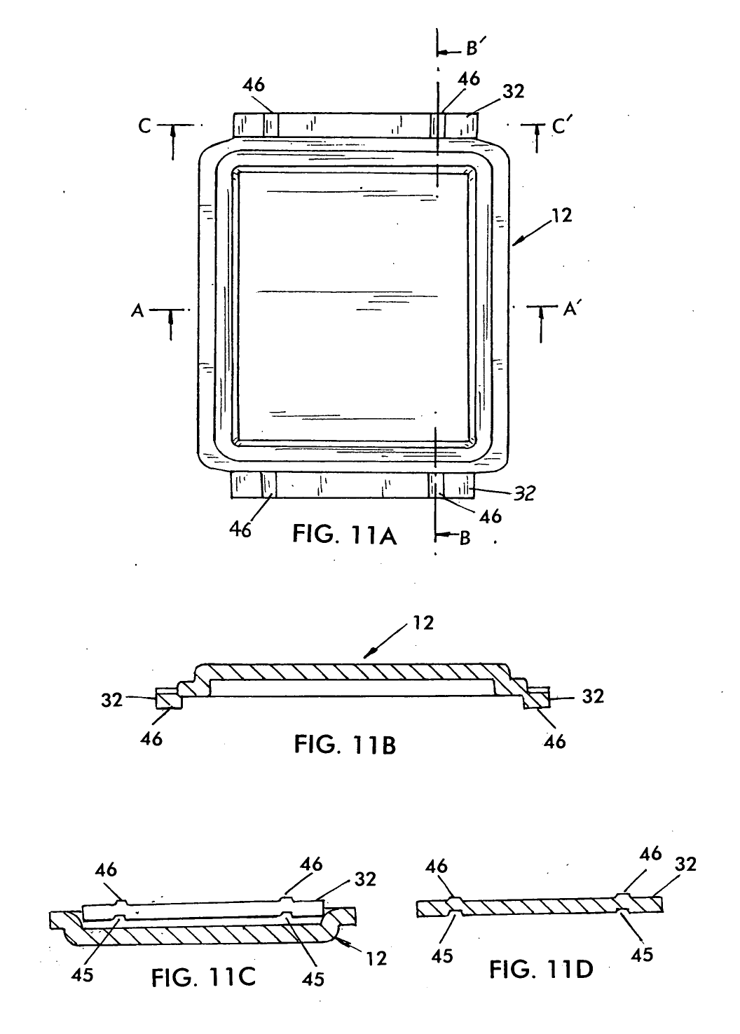

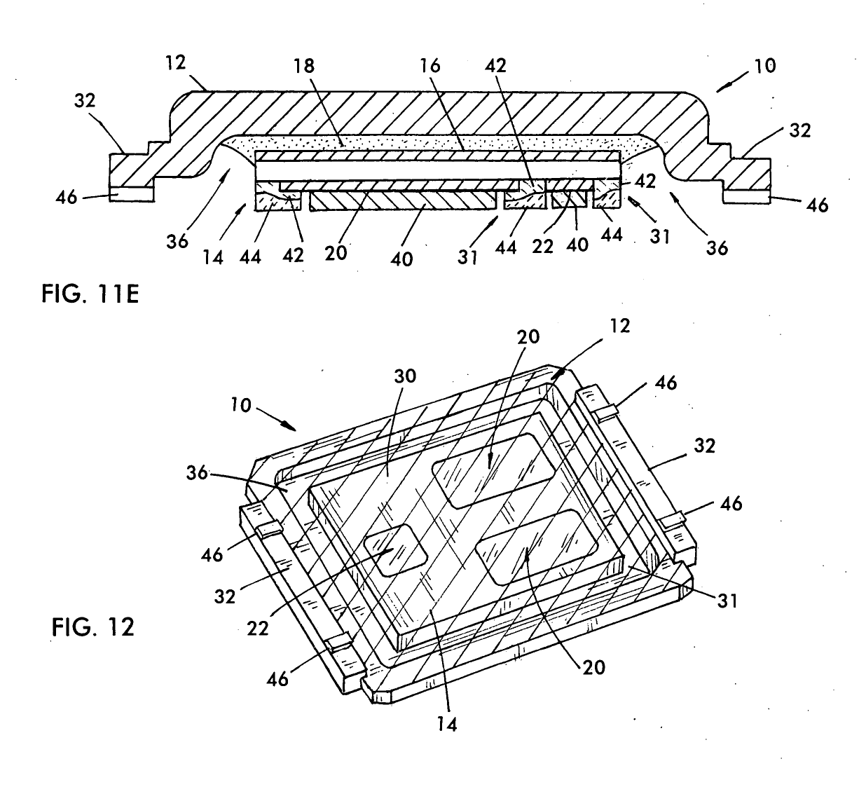

Referring to FIGS. 11A-11D, according to another aspect of the present invention, can 12 may be dimpled such that rails 32 will include bumps 46 on the assembly side (the side mounted on the substrate or circuit board) thereof. That is, for example, can 12 may be modified to include two spaced dimples 45 on each rail 32 resulting in two bumps 46 on the opposite side. Dimples 45 may be fabricated by punching or the like process to deform each rail 32 as desired to have bumps 46 on the assembly side thereof.

Referring next to FIG. 11E, in an improved package according to another aspect of the present invention, can 12 having bumps 46 is used to form a package according to an alternative embodiment. Bumps 46 increase clearance 33 (FIG. 8) between passivation 30 on die 14 and circuit board 28. Solder bodies 40 may also help in this regard and are preferably included with a can having bumps 46. The stand-off will enable a larger gap between die 14 and circuit board 28 to aid de-gassing, and release of volatile flux components. Note that the package shown by FIG. 11E includes a die having solder bodies 40 formed on electrodes thereof. It should be noted, however, a can 12 having bumps 46 as described herein is not limited to the specific die shown by FIG. 11E, but may include any other die including a die without solder bodies 40. Furthermore, preferably a two layer passivation 31 is used with the package illustrated by FIG. 11E. However, it should be noted that other passivation bodies including a single layer passivation body (e.g. passivation body 30) may be used without deviating from the scope and the spirit of the present invention.

In a device that includes a solder body disposed thereon the flux flushing clearance 33 can be increased to 110 μm, while in a device which includes bumps 46 clearance 33 can be increased to 175 μm.

Referring next to FIG. 12, in an improved package according to an aspect of the present invention moat 36 may be filled with passivation body 31 (illustrated by slanted lines) having first passivation 42 and second passivation 44. Note that the filling of moat 36 may not be required for low voltage die, but may be used for mid-voltage die or higher. Further, note that passivation 31 may be extended to cover all or part of the flange portions of can 12 if desired to increase the creepage distance between the high current portions of package 10. Also, note that die 14 may optionally include a solder body 40 on its source and gate electrodes. Furthermore, a single passivation body (e.g. passivation body 30) may be used without deviating from the present invention, although a double layer passivation 31 is preferred. Also, optionally, can 12 may include bumps 46.

A preferred die 10 for a package according to the present invention is 200 μm thick, but a die having another thickness can be used without deviating from the scope and the spirit of the present invention. Can 12 in a package according to any of the embodiments of the present invention may be preferably formed with copper, a copper alloy, or the like, and may be plated with silver, gold, or the like material, although other materials can be used without deviating from the scope of the present invention. It should also be noted that a package according to any of the embodiments of the present invention can be assembled with a MOSFET, an IGBT, a diode, or any other suitable power semiconductor device.

Although the present invention has been described in relation to particular embodiments thereof, many other variations and modifications and other uses will become apparent to those skilled in the art. It is preferred, therefore, that the present invention be limited not by the specific disclosure herein, but only by the appended claims.

What is claimed is:

1. A semiconductor package comprising:
a conductive clip having a web portion;
a semiconductor die having a first power electrode electrically and mechanically connected to said web portion, and a second power electrode opposite said first power electrode;
a passivation body formed over at least said second power electrode; and
a solder body on said second power electrode and extending beyond said passivation body.

2. The package of claim 1, wherein said solder body is comprised of a lead free solder.

3. The package of claim 1, wherein said solder body is comprised of SnAgCu.

4. The package of claim 1, wherein said solder body is comprised of SnSb.

5. The package of claim 1, wherein said clip includes a wall spaced from and surrounding said die, said wall including a flange portion, wherein said passivation body resides within said space between said die and said wall and fully covers said flange portion.

6. The package of claim 1, wherein said passivation body includes a first passivation layer comprised of a first passivation material and a second passivation layer comprised of a second passivation material.

7. A package according to claim 6, wherein said first passivation material is a carbon based polymer and said second passivation material is a silicon based polymer.

8. A package according to claim 6, wherein said first passivation material is a carbon based epoxy and said second passivation material is a silicon based epoxy.

9. A package according to claim 6, wherein said clip includes a wall spaced from and surrounding said die, said wall including a flange portion, wherein said passivation body resides within said space between said die and said wall and filly covers said flange portion.

10. A package according to claim 1, wherein said conductive clip includes two opposing rail portions each including a plurality of bumps.

11. A package according to claim 1, wherein said die further includes a control electrode adjacent said second power electrode.

12. A package according claim 1, wherein said die is a power MOSFET.

13. A semiconductor package comprising:
a conductive clip having a web portion;
a semiconductor die having a first power electrode electrically and mechanically connected to said web portion, and a second power electrode opposite said first power electrode; and
a passivation body formed over at least said second power electrode, said passivation body including an opening exposing said second power electrode, and having a first passivation layer comprised of a first passivation material and a second passivation layer comprised of a second passivation material.

14. A package according to claim 13, wherein said first passivation material is a carbon based polymer and said second passivation material is a silicon based polymer.

15. A package according to claim 13, wherein said first passivation material is a carbon based epoxy and said second passivation material is a silicon based epoxy.

16. A package according to claim 13, wherein said clip includes a wall spaced from and surrounding said die, said wall including a flange portion, wherein said passivation body resides within said space between said die and said wall and fully covers said flange portion.

17. A package according to claim 13, wherein said conductive clip includes two opposing rail portions each including a plurality of bumps.

18. A package according to claim 13, wherein said die further includes a control electrode adjacent said second power electrode.

19. A package according to claim 13, wherein said die is a power MOSFET.

20. A package according to claim 13, further comprising a solder body on said second power electrode and extending beyond said passivation body.

21. A package according to claim 20, wherein said solder body is comprised of a lead free solder.

22. A package according to claim 20, wherein said solder body is comprised of SnAgCu.

23. A package according to claim 20, wherein said solder body is comprised of SnSb.

24. A package according to claim 13, wherein said clip includes a wall spaced from and surrounding said die, said wall including a flange portion, wherein said passivation body resides within said space between said die and said wall and fully covers said flange portion.

25. A semiconductor package comprising:
a conductive clip having a web portion, and two opposing rail portions each including a plurality of bumps;
a semiconductor die having a first power electrode electrically and mechanically connected to said web portion, and a second power electrode opposite said first power electrode; and
a passivation body formed over at least said second power electrode;
wherein said second power electrode is configured for connection to a conductive pad on a support body by a conductive adhesive, and said bumps are configured to space said passivation body from said support body to provide a clearance between said passivation body and said support body.

26. The package of claim 25, wherein said clearance is up to 175 μm.

27. The package of claim 25, further comprising a solder body on said second power electrode and extending beyond said passivation body.

28. The package of claim 27, wherein said solder body is comprised of a lead free solder.

29. The package of claim 28, wherein said solder body is comprised of SnAgCu.

30. The package of claim 28, wherein said solder body is comprised of SnSb.

31. The package of claim 25, wherein said clip includes a wall spaced from and surrounding said die, said wall including a flange portion, wherein said passivation body resides within said space between said die and said wall and fully covers said flange portion.

32. The package of claim 25, wherein said passivation body includes a first passivation layer comprised of a first passivation material and a second passivation layer comprised of a second passivation material.

33. The package of claim 32, wherein said first passivation material is a carbon based polymer and said second passivation material is a silicon based polymer.

34. The package of claim 32, wherein said first passivation material is a carbon based epoxy and said second passivation material is a silicon based epoxy.

35. The package of claim 25, wherein said die further includes a control electrode adjacent said second power electrode.

36. The package of claim 25, wherein said die is a power MOSFET.
